(19) United States
(12) Patent Application Publication
(10) Pub. No.: US 2024/0244753 A1
(43) Pub. Date: Jul. 18, 2024

(54) METHOD FOR MANUFACTURING A FURNITURE OR CONSTRUCTION ELEMENT

(71) Applicant: HOMAG GmbH, Schopfloch (DE)

(72) Inventors: Ludwig ALBRECHT, Dornstetten-Aach (DE); Felix KRESPACH, Vöhringen (DE)

(21) Appl. No.: 18/559,311

(22) PCT Filed: May 10, 2022
(86) PCT No.: PCT/EP2022/062578

§ 371 Date: Nov. 6, 2023

(30) Foreign Application Priority Data
May 12, 2021 (DE) 10 2021 112 435.2

(51) Int. Cl. H05K 1/16; A47B 96/20

(52) U.S. Cl. CPC H05K 1/16; A47B 96/20

(57) ABSTRACT

Method for manufacturing a furniture or construction element (1), comprising the steps of providing a workpiece (2), which preferably consists at least in part of wood, wood material, plastic or the like, applying a coating material (4) to at least a portion of the surface of the workpiece (2), and providing at least one electronic component (10, 10′) on the coating material (4), characterised in that at least one electronic component (10, 10′) is printed at least in part onto the coating material (4).

### TECHNICAL FIELD

The invention relates to a method for manufacturing a furniture or construction element according to the preamble of patent claim 1.

### PRIOR ART

In the field of the furniture and construction elements industry, the components often consist of chipboard provided with various coating materials on the surface thereof. There is an increasing desire to also provide such components with electric and electronic components, for example to be able to display information or operate switches.

For example, DE 10 2016010583 A1 discloses a workpiece provided with a decorative film, wherein electronic components such as sensors, actuators or displays are provided in the film and are connected by means of a printed circuit. However, experience has shown that the arrangement of various electronic components is complex and has considerable requirements in terms of logistics and storage. Furthermore, it is also difficult to adapt the respective components to the corresponding workpieces, for example to the dimensions thereof, and/or this leads to even greater storage requirements.

### DESCRIPTION OF THE INVENTION

It is therefore an object of the invention to provide a method for manufacturing a furniture or construction element of the aforementioned type, for which electronic components can be provided in a simple and flexible manner.

This object is solved according to the invention by means of a method for manufacturing a furniture or construction element according to claim 1. Particularly preferred further developments of the invention are specified in the dependent claims.

The idea forming the basis for the invention is to integrate the manufacture of the at least one electronic component into the method for manufacturing the furniture or construction element so that the properties of the electronic component can be set at an extremely late stage and in knowledge of the respective furniture or construction element. For this purpose, it is provided according to the invention that at least one electronic component is printed at least in part on the coating material. As a result hereof, at least one electronic component can be provided on or in the respective furniture or construction element in a particularly simple and flexible manner. Logistics are at the same time simplified considerably and, with the exception of consumables for the printing process, storage can largely be dispensed with.

The at least one electronic component can furthermore also be integrated particularly well since no special recesses or indentations are generally required for printing the at least one electronic component.

This also applies in particular if, according to a further development of the method according to the invention, the at least one electronic component is configured as a single layer. This not only results in a particularly simple and rapid printing process, but the electrical connection of the at least one electronic component is also simplified since a total of only one layer is required for the electronic component, electrodes and other electric circuits. The layer may, for example, be printed in a single-pass or multi-pass process.

Multi-layer electronic components may also be advantageous within the context of the invention, in particular if a plurality of functions are supposed to be combined in one component.

The at least one electronic component may be configured in a variety of different manners within the context of the present invention. However, specific optical and functional effects result if, according to a further development of the method according to the invention, at least one electronic component comprises a display. As a result hereof, various pieces of information can be displayed on the one hand, and various light and illumination effects can be achieved on the other.

It is particularly preferred that at least one electronic component comprises a light-emitting diode (LED), preferably an organic light-emitting diode (OLED). These components combine diverse and variable lighting and illumination effects with low power consumption. Such electronic components have furthermore recently become suitable in particular for a single-layer structure, which can advantageously also be printed, at least in part.

It is alternatively or additionally provided according to a further development of the invention that at least one electronic component comprises a sensor, preferably a touch sensor and/or a proximity sensor such as, in particular, a (for example organic) photodiode. Numerous other functions can be provided in the respective furniture or construction element in this manner, such as control panels for electric devices, motion detectors, light barriers, etc.

It is alternatively or additionally provided according to a further development of the invention that the at least one electronic component comprises a transmitting and/or receiving unit such as, in particular, a transceiver. This results in various different communication possibilities without requiring a high level of manufacturing effort.

It is furthermore provided according to a further development of the invention that the at least one electronic component comprises a computing unit such as, in particular, a gate and/or a CPU, so that the range of possible functions can be greatly increased whilst keeping the required manufacturing effort low thanks to the printing process.

It is also provided according to a further development of the invention that electrically conductive and/or organic ink is used for printing the at least one electronic component. As a result hereof, a wide variety of electronic components can be printed effectively, and the use of organic inks has the advantage, in addition to a simple manufacturing process, that expensive ingredients, such as in particular rare earth metals, can be dispensed with in whole or in part, and thus valuable resources can be conserved. It should furthermore be noted that instead of using a conductive ink, it is also possible within the context of the invention to use ink that is only rendered conductive by subsequent action (such as energy input by means of a laser, for example).

It is also provided according to a further development of the invention that the at least one electronic component is provided with a cover layer, which is preferably configured as a protective layer and/or a contrast layer. Both the durability and functionality of the at least one component can be further increased as a result hereof.

Even though the at least one electronic component can, in principle, be printed onto the coating material at any time, it is preferred according to a further development of the invention that the at least one electronic component is printed onto the coating material after the coating material has been applied at least in part to the workpiece. As a result hereof, the electronic component can, on the one hand, be tailored in a particularly precise manner to the respective workpiece. In addition, however, the production process is also simplified since the coating material does not have to be specifically aligned with respect to the workpiece and production logistics are simplified.

By means of the method according to the invention, workpieces can furthermore be provided with at least one electronic component at any time, where required also as a retrofit.

It is also provided according to a further development of the invention that the workpiece comprises a power supply and/or a data transmission interface that is/are connected to the at least one electronic component. A power supply can on the one hand be understood to mean a power storage device such as a battery or rechargeable battery, but can on the other hand also mean a power supply interface, via which a connection to a power network or an external power storage device can be established. The provision of solar modules or other power generation units is also conceivable as a power supply. As a result hereof, a reliable operation of the at least one electronic component can overall be ensured.

The data transmission interface may also be configured as an at least partially printed transmitting and/or receiving unit, as described above. A data transmission interface thereby enables increased functionality of the at least one electronic component since a connection to other electronic components or other units can, for example, be established via the data transmission interface.

In this respect, it is provided according to a further development of the invention that the at least one electronic component is coupled to a control unit of a machine, such as in particular a household appliance, and/or to a wireless network, such as in particular a WLAN router or possibly also a mobile radio connection. The aforementioned data transmission interface can advantageously be used for this coupling. An extremely varied functionality is in any case achieved as a result hereof since not only can simple information such as a time be displayed by means of the at least one electronic component, but also, for example, complex information of an adjacent household appliance can be shown and control of the household appliance (for example, switching on and off or starting a specific work programme) can also be performed.

It is furthermore possible to display information received, for example, from the Internet via a WLAN router, with it also being possible in this case to issue instructions or make inputs via the WLAN router in order to carry out interactive communication with a wide variety of websites, servers or devices via the WLAN router and potentially the Internet.

### BRIEF DESCRIPTION OF THE DRAWINGS

Further features and advantages of a device, a use and/or a method are apparent from the following description of embodiments with reference to the accompanying drawings. In these drawings,

FIG. 1 schematically shows a view of a furniture group according to an embodiment of the invention;

FIG. 2 schematically shows detailed views and embodiments of possible electronic components.

### Description of Embodiments

Preferred embodiments of the invention will be described in detail below with reference to the accompanying figures.

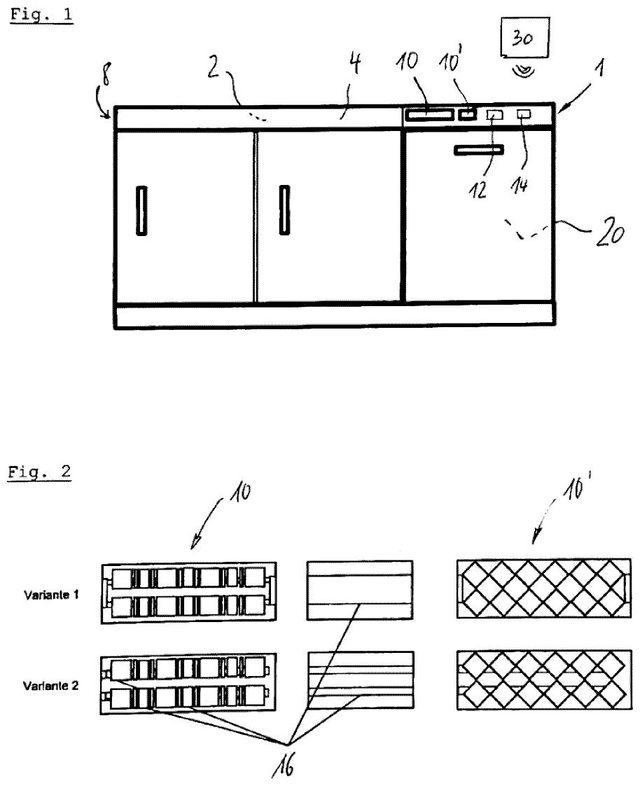

A group of furniture 1 according to one embodiment of the invention is schematically shown as a side view in FIG. 1. Purely by way of example, this is a group of kitchen furniture 1, in which a number of base cabinets are provided underneath a worktop 8. The right-hand section of the worktop 8, together with the base cabinet therebelow, forms kitchen furniture 1, in which a household appliance 20, such as a dishwasher, is housed.

The worktop 8 shown in FIG. 1 comprises two electronic components 10 and 10′ on the surface facing the viewer, which, in the present embodiment, are configured, for example, as a display 10 and a sensor 10′. The display 10 may, for instance, be a light-emitting diode (LED), in particular an organic light-emitting diode (OLED). This display 10 may display various pieces of information, such as the work programme or remaining time of the household appliance 20, the time, or any other information that may also be obtained from the Internet, for example.

A possible structure of the display 10 is shown in two variants 1 and 2 in FIG. 2. Shown herein by way of an example are organic light-emitting diodes (OLEDs), each of which is supplied with power via supply lines 16.

Also shown in FIG. 2 are possible configurations of the sensor 10′, which is designed in the present embodiment as a capacitive or inductive proximity sensor. The sensor 10′ may, for example, comprise an organic photodiode (OPD).

The two configurations have in common that they are printed, single-layer or multi-layer electronic components 10, 10′ that have been applied to the coating material by printing with a conductive organic ink. It is particularly preferred that the ink is free of rare earth metals.

Even though this is not shown in FIG. 1, at least one electronic component may comprise a transmitting and/or receiving unit such as, in particular, a transceiver. At least one electronic component may also comprise a computing unit such as, in particular, a gate and/or a CPU. Various combination devices such as transponders are also possible within the context of the invention.

The method for manufacturing the furniture illustrated in FIG. 1 thus first of all involves providing one or more plate-shaped workpieces 2, which in the present embodiment consist, for example, of wood, wood materials, plastic or the like, such as are widely used in the field of the furniture and construction elements industry.

A coating material 4, such as decorative paper, plastic edging or a wide variety of other materials, such as a veneer, is then applied to the surface of the workpiece. The electronic components 10, 10′ can now be printed onto the coating material 4, with it also being possible, in principle, to print at least one electronic component onto the coating material in advance (before the coating process).

Subsequently, at least one electronic component 10, 10′ may be provided with a cover layer, such as a protective film or a contrast film, with it also being possible to provide other cover layers instead of a film, for example also by means of a printing process.

Conductive tracks, electrodes (such as the supply lines 16 shown in FIG. 2) or other electrical tracks may also be printed, if required, during the manufacturing process if they are not otherwise provided or already present. An electrical connection to a power supply 12 and a data transmission interface 14, which are schematically shown in FIG. 1, can also be established via these conductive tracks.

The power supply 12 may, for example, establish a connection to a conventional power network or also to a power source of the corresponding household appliance 20.

In the present embodiment, the data transmission interface is configured as a WLAN interface that communicates with a WLAN router 30 (cf. FIG. 1) and, in this manner, can also establish a connection to and via the Internet as required. Instead of a WLAN connection, a wired LAN connection or a connection to an arbitrary wireless network may, for example, also be used.

Thanks to this configuration, a wide variety of information can be displayed by means of the display 10, both with respect to the household appliance 20 or any other machines and using the Internet or any other data sources. By means of the sensor 10′, it is furthermore possible to control the household appliance 20, and arbitrary commands can be issued to and via the Internet or another suitable data connection.

1. A method for manufacturing a furniture or construction element comprising the steps of:
providing a workpiece, which preferably consists at least in part of wood, wood material, plastic or the like,
applying a coating material to at least a portion of the surface of the workpiece, and
providing at least one electronic component on the coating material
characterised in that
at least one electronic component is printed at least in part onto the coating material.

2. The method according to claim 1, wherein the at least one electronic component has a single-layer or multi-layer structure.

3. The method according to claim 1, wherein the at least one electronic component comprises a display, in particular a light-emitting diode, preferably an organic light-emitting diode (OLED).

4. The method according to claim 1, wherein the at least one electronic component comprises a sensor, preferably a touch sensor and/or a proximity sensor such as, in particular, a photodiode.

5. The method according to claim 1, wherein the at least one electronic component comprises a transmitting and/or receiving unit such as, in particular, a transceiver.

6. The method according to claim 1, wherein the at least one electronic component comprises a computing unit such as, in particular, a gate and/or a CPU.

7. The method according to claim 1, wherein electrically conductive and/or organic ink, which is preferably free of rare earth metals, is used for printing the at least one electronic component.

8. The method according to claim 1, wherein the at least one electronic component is provided with a cover layer, which is preferably configured as a protective layer and/or a contrast layer.

9. The method according to claim 1, wherein the at least one electronic component is printed onto the coating material after the coating material has been applied at least in part to the workpiece.

10. The method according to claim 1, wherein the workpiece comprises a power supply and/or a data transmission interface that is/are connected to the at least one electronic component.

11. The method according to claim 1, wherein the at least one electronic component is coupled to a control unit of a machine, such as in particular a household appliance, and/or to a wireless network, such as in particular a WLAN router.
